(19) United States
(12) Patent Application Publication
(10) Pub. No.: US 2006/0057780 A1
(43) Pub. Date: Mar. 16, 2006

(54) Manufacturing apparatus of semiconductor devices, and method of manufacturing semiconductor devices

(76) Inventors: Shigehisa Tajimi, Sakata (JP); Takeshi Yasuda, Fujishima (JP)

Correspondence Address: HARNESS, DICKEY & PIERCE, P.L.C., P.O. BOX 828, BLOOMFIELD HILLS, MI, 48303, US

(21) Appl. No.: 11/212,355

(22) Filed: Aug. 26, 2005

(30) Foreign Application Priority Data
Sep. 14, 2004 (JP) 2004-267227

(51) Int. Cl. H01L 21/58

(52) U.S. Cl. 438/118; 438/455; 438/612; 156/349; 156/497

(57) ABSTRACT

A method for manufacturing semiconductor devices, comprises: mounting a substrate on a bonding stage; pressing the substrate to the bonding stage by blowing a compressed air from the upper face side of the substrate; causing the bonding stage to adsorb the substrate by exhausting air from the lower face side of the substrate, and bonding a semiconductor chip to the substrate.

### BACKGROUND OF THE INVENTION

1. Technical Field

The present invention relates to a manufacturing apparatus of semiconductor devices, and a method for manufacturing semiconductor devices.

2. Related Art

In recent years, the electronic apparatus, such as notebook PCs and cellular phones are further being miniaturized, being reduced in weight, and being sophisticated. Moreover, the wiring of semiconductor ICs is also being formed in further high-definition. Also in the flexible copper-clad laminates used for a chip-on film (COF) method for mounting electronic components, such as IC and LSI, it is indispensable that circuit patterns to be formed will be formed in further finer pitch than in the pitch of the present state.

On the other hand, the flexible copper-clad laminates are manufactured by gluing together a metallic foil such as a copper foil to the surface of a heat-resistant film represented by a polyimide film via an adhesive formed of an epoxy system resin adhesive or the like, and etching this metallic foil into a predetermined pattern. For the conventional flexible copper-clad laminate, a thickness (the average thickness) of 75 μm of the heat-resistant films is prevailing, however, with the reduction in weight and with the finer pitch in recent years, the heat-resistant film with a thickness of 50 μm or less is under investigation.

Japanese Unexamined Patent Publication No. 10-214865 is an example of the related art.

When compress-bonding an electronic component to a circuit pattern with an application of heat, the heat-resistant film will deform due to the heat thereof to thereby appear as warping and lifting of the flexible copper-clad laminate, giving substantial influences at the time of mounting IC packages, as described below.

With the miniaturization and reduction in weight of the electronic apparatus, the circuit patterns formed in the flexible copper-clad laminate is becoming such remarkably fine in pitch as several 10 μm or less, and thus even a small deformation of the flexible copper-clad laminate easily becomes the cause of bonding failures.

### SUMMARY

An advantage of the invention is to provide a manufacturing apparatus of semiconductor devices and a method for manufacturing the semiconductor devices, capable of resolving such problems and improving the reliability of the electric bonding by compress-bonding the electronic components for sure in the state that the substrate is kept flat.

(1) According to a first aspect of the invention, a method for manufacturing semiconductor devices includes the steps of: mounting a substrate on a bonding stage; pressing the substrate to the bonding stage by blowing a compressed air from the upper face side of the substrate; causing the bonding stage to adsorb the substrate by exhausting air from the lower face side of the substrate; and bonding a semiconductor chip to the substrate. According to the invention, by blowing a compressed air so as to press, from the upper face side of the substrate, the substrate to the substrate mounting face of the bonding stage in which the substrate is to be mounted, it becomes easy to adsorb the substrate to the substrate mounting face side of the substrate from the lower face side of the substrate. For this reason, warping and lifting of the substrate will be reduced, and thereby the compress-bonding of the electronic components can be carried out for certain in the state that the substrate is kept flat. Accordingly, it is possible to provide the method for manufacturing semiconductor devices capable of increasing the reliability of the electric bonding.

(2) According to a second aspect of the invention, a manufacturing apparatus of semiconductor devices includes: a bonding stage for mounting a substrate in which a semiconductor chip is to be mounted, the bonding stage being provided with an air outlet for exhausting air in the lower face side of the substrate; a blower for blowing a compressed air so as to press the substrate to the bonding stage from the upper face side of the substrate; and a bonding tool for bonding the semiconductor chip to the substrate. According to the invention, by blowing a compressed air so as to press, from the upper face side of the substrate, the substrate to the substrate mounting face of the bonding stage in which the substrate is to be mounted, it becomes easy to adsorb the substrate to the substrate mounting face side of the substrate from the lower face side of the substrate. For this reason, warping and lifting of the substrate will be reduced, and thereby the compress-bonding of the electronic components can be carried out for certain in the state that the substrate is kept flat. Accordingly, it is possible to provide the manufacturing apparatus of semiconductor devices capable of increasing the reliability of the electric bonding.

### BRIEF DESCRIPTION OF THE DRAWINGS

The invention will be described with reference to the accompanying drawings, wherein like numbers refer to like elements, and wherein:

FIG. 1 is a view showing a semiconductor device concerning an embodiment of the invention;

FIG. 2 is a view showing a manufacturing apparatus of semiconductor devices concerning an embodiment of the invention;

FIG. 3 is a view showing a state that a substrate concerning the embodiment of the invention is stuck to the compress-bonding face;

FIG. 4 is a view showing a manufacturing apparatus of semiconductor devices concerning a modification of the embodiment of the invention; and

FIG. 5 is a sectional view taken along the line V-V line of FIG. 4.

### DESCRIPTION OF THE EMBODIMENTS

Hereinafter, embodiments of the invention will be described with reference to the accompanying drawings.

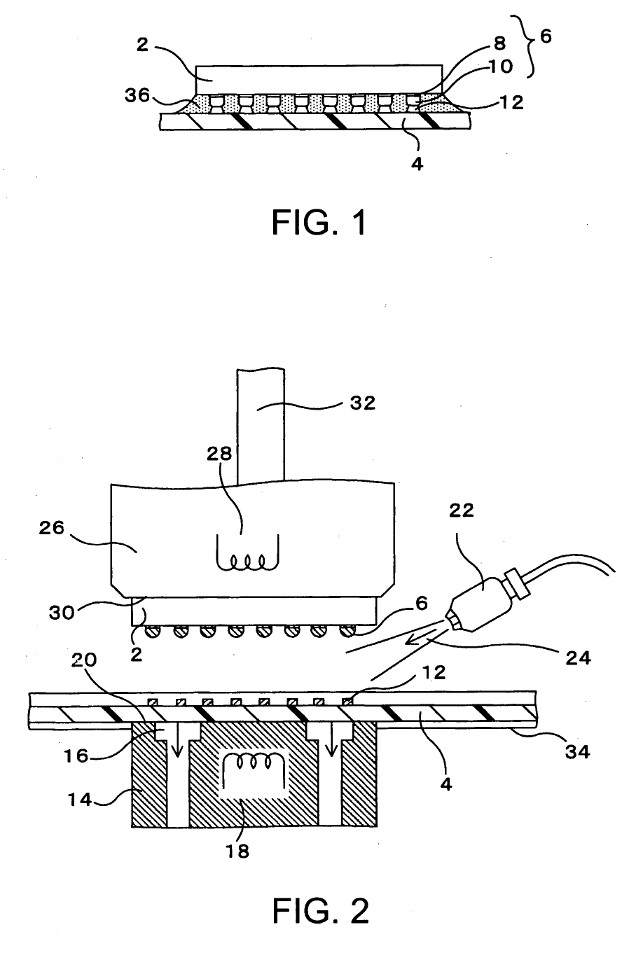

FIG. 1 is a view showing a semiconductor device concerning an embodiment of the invention. The semiconductor device concerning this embodiment has a semiconductor chip 2 and a substrate 4. The semiconductor chip 2 is an integrated circuit chip. The semiconductor chip 2 has a plurality of electrodes 6. Although each electrode 6 includes a pad 8 and a bump 10, the bump 10 may be eliminated so that the pad 8 only may form the electrode. The pad 8 is formed from aluminum, for example, and the bump 10 is formed from gold, for example. The bump 10 may be formed by plating or may be formed of the ball of wire bonding. The substrate 4 may be a flexible substrate or a film, or may be a rigid substrate. The substrate 4 may be the one in which a plurality of leads 12 are formed on a base substrate formed from a polyimide resin, for example. In this case, the circuit pattern is formed by the plurality of leads 12. The semiconductor chip 2 is face-down bonded to the substrate 4. The electrodes 6 are bonded to the leads 12.

Next, FIG. 2 is a view showing a manufacturing apparatus of semiconductor devices concerning an embodiment of the invention.

As shown in FIG. 2, the manufacturing apparatus of semiconductor devices according to this embodiment has a bonding stage 14, at the fixing side, arranged downward in the vertical direction. The bonding stage 14 is provided with an air outlet 16 for exhausting the air in the lower face side of the substrate 4, and a heater 18, and has a compress-bonding face 20 whose upper face is processed to be flat. The bonding stage 14 is heated to be in use. The substrate 4 is set in the compress-bonding face 20 of the bonding stage 14.

The manufacturing apparatus of semiconductor devices has a blower 22. The blower 22 blows a compressed air 24 on the upper face side of the substrate 4 so as to press the substrate 4 to the compress-bonding face 20 of the bonding stage 14. The blower 22 is supported by a support (not shown).

The manufacturing apparatus of semiconductor devices has a bonding tool 26. The bonding tool 26 is provided with a heater 28, and has a bonding face 30 at the tip thereof. The bonding tool 26 is heated to be in use. For example, the bonding tool 26 is used at around 400 through 500° C. The bonding tool 26 bonds all together the plurality of leads 12 of the substrate 4 to the plurality of electrodes 6 of the semiconductor chip 2. It is preferable that the bonding face 30 be kept flat. In particular, the bonding tool 26 is heated to be in use, and it is therefore preferable that the bonding face 30 be kept flat while being heated. The bonding tool 26 is attached to a pressurized piston (not shown) via a rod 32, as to be elevatable in the vertical direction of the view by the piston drive.

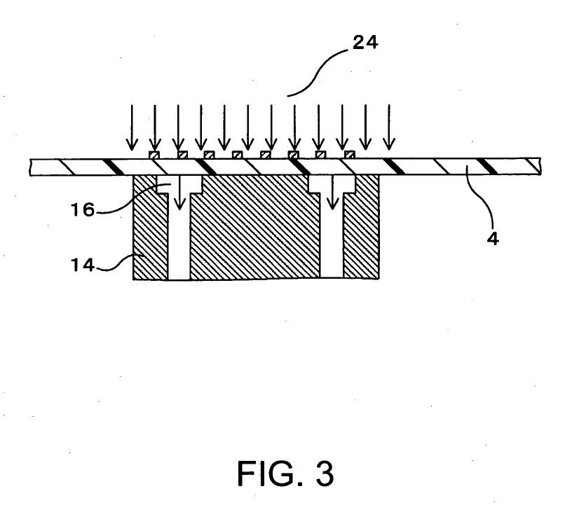

Next, a method for manufacturing semiconductor devices includes the step of pressurizing and heating, thereby bonding the electrodes 6 of the semiconductor chip 2 to the leads 12 formed in the substrate 4. For example, the semiconductor chip 2 is mounted to the substrate 4 with the face-down bonding process. Specifically, as shown in FIG. 2, the semiconductor chip 2 is set to the bonding tool 26 so that the face, in which the electrodes 6 of the semiconductor chip 2 are formed, is opposed to the face in which the leads 12 of the substrate 4 are formed. Furthermore, the substrate 4 is moved on a rail 34 to be set to the bonding stage 14. Next, the upper face side of the substrate is made a high pressure space by blowing the compressed air 24 on the upper face side of the substrate 4 with the blower 22, and at the same time the lower face side of the substrate 4 is made a low pressure space by exhausting, from an air outlet 16 of the bonding stage 14, the air in the lower face side of the substrate 4. The high pressure space on the upper face side of the substrate 4 presses the upper face side of the substrate 4 downward, and presses the substrate 4 on the compress-bonding face 20 of the bonding stage 14. The low pressure space in the lower face side of the substrate 4 causes the substrate 4 to be adsorbed to the bonding stage 14. FIG. 3 shows a state that the substrate 4 is stuck to the compress-bonding face 20 of the bonding stage 14 by the high pressurizing on the upper face side of the substrate 4 due to the compressed air 24, and by the low pressurizing in the lower face side of the substrate 4 due to the exhaust at the air outlet 16.

Next, the electrodes 6 and leads 12 (the semiconductor chip 2 and substrate 4) are aligned on the bonding stage 14. Then, the bonding tool 26 starts to descend downward of the view by an actuation of the pressurized piston (not shown) to thereby applying pressure with respect to the electrodes 6 and leads 12. Then, at the same time of the starting of an application of pressure with respect to the electrodes 6 and leads 12, or after the application of pressure, heating to at least one of the bonding tool 26 and the bonding stage 14 will be started. In this manner, at the same time of the starting of the application of pressure with respect to the electrodes 6 and leads 12, or after the starting, the electrodes 6 and leads 12 will be heated up, and the temperature of the bonding portion of the electrodes 6 and leads 12 will be increased higher than the bonding temperature of the electrodes 6 and leads 12.

Through the above process, the semiconductor chip 2 can be bonded to the substrate 4 by bonding the electrodes 6 to the leads 12. Thereafter, an under-fill material 36 may be filled in between the semiconductor chip 2 and electrode 6, as shown in FIG. 1.

According to the invention, the alignment of the electrodes 6 and leads 12 are made in the state that the substrate is kept flat, therefore, the misalignment of the bonding positions of the electrodes 6 and the leads 12 will be reduced. Subsequently, the electrodes 6 and leads 12 will be pressurized and heated up. For this reason, the deterioration of reliability of the semiconductor device due to the bonding failures between the electrodes 6 and leads 12 can be prevented.

(Modification)

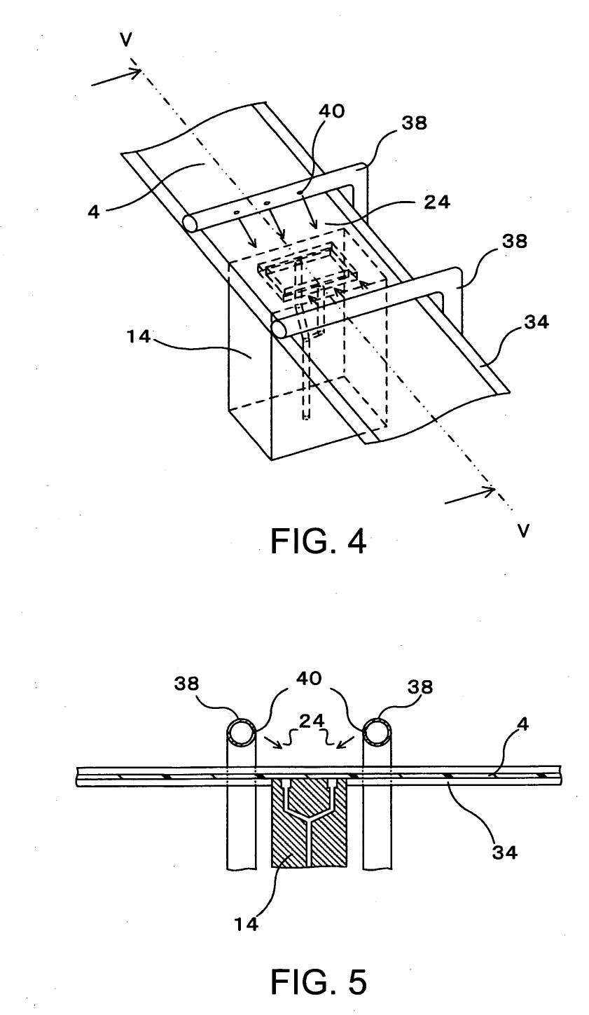

FIG. 4 is a view showing a manufacturing apparatus of semiconductor devices concerning a modification of the embodiment of the invention. FIG. 5 is a sectional view taken along the V-V line of FIG. 4. In the examples shown in FIG. 4 and FIG. 5, the manufacturing apparatus of semiconductor devices has a blower 38. The blower 38 has a plurality of jet nozzles 40 provided therein. The plurality of jet nozzles 40 are arranged in two rows so as to intersect with a rail 34. The plurality of jet nozzles 40 are provided so as to face to the inner sides of the arrangement of the two rows. The blower 38 blows the compressed air 24 to a large area in the upper face side of the substrate 4 with the plurality of jet nozzles 40. As to the other configurations thereof, the contents described in the above embodiments can be applied. As to the method for manufacturing semiconductor devices shown in FIG. 4, the matters described in the above embodiments can be applied. Provided, however, that, the upper face side of the substrate 4 is made a high pressure space by blowing a compressed air on the upper face side of the substrate 4 with the blower 38.

The invention is not restricted to the above-described embodiments, and various modifications can be made. For example, the invention includes substantially the same configurations (for example, the configurations having the same function, method and results, or the configurations having the same objectives and results) as the configurations described in the embodiments. Moreover, the invention includes the configurations that replace the non-essential portions in the configurations described in the embodiments. Moreover, the invention includes the configurations attaining the same operational effects as those of the configurations described in the embodiments, or the configurations capable of attaining the same objectives. Moreover, the invention includes the configurations in which the known arts are added to the configurations described in the embodiments. Furthermore, the invention includes the contents limitedly excluding any of the technical matters described in the embodiments. Or the invention includes the contents limitedly excluding the known arts from the above-described embodiments.

What is claimed is:

1. A method for manufacturing semiconductor devices, comprising:
mounting a substrate on a bonding stage;
pressing the substrate to the bonding stage by blowing a compressed air from the upper face side of the substrate;
causing the bonding stage to adsorb the substrate by exhausting air from the lower face side of the substrate, and
bonding a semiconductor chip to the substrate.

2. A manufacturing apparatus of semiconductor devices, comprising:
a bonding stage for mounting a substrate in which a semiconductor chip is to be mounted, the bonding stage being provided with an air outlet for exhausting air in the lower face side of the substrate;
a blower for blowing a compressed air so as to press the substrate to the bonding stage from the upper face side of the substrate; and
a bonding tool for bonding the semiconductor chip to the substrate.
